(19) United States
(12) Patent Application Publication
(10) Pub. No.: US 2003/0003230 A1
(43) Pub. Date: Jan. 2, 2003

(54) Method for manufacturing thin film

(76) Inventors: Yeong-kwan Kim, Kyungki-do (KR); Sang-in Lee, Kyungki-do (KR); Chang-soo Park, Kyungki-do (KR); Sang-min Lee, Seoul (KR)

Correspondence Address: VOLENTINE FRANCOS, PLLC, SUITE 150, 12200 SUNRISE VALLEY DRIVE, RESTON, VA, 20191, US

(21) Appl. No.: 10/224,427

(22) Filed: Aug. 21, 2002

Related U.S. Application Data
(62) Division of application No. 09/414,526, filed on Oct. 8, 1999.

(30) Foreign Application Priority Data
Oct. 16, 1998 (KR) 98-43353

(51) Int. Cl. C23C 16/00

(52) U.S. Cl. 427/255.394

(57) ABSTRACT

A method for manufacturing a thin film includes the steps of loading a substrate into a reaction chamber, and terminating the surface of the substrate loaded into the reaction chamber by a specific atom. A first reactant is chemically adsorbed on the terminated substrate by injecting the first reactant into the reaction chamber including the terminated substrate. After removing the first reactant physically adsorbed into the terminated substrate, a solid thin film is formed through chemical exchange or reaction of the chemically adsorbed first reactant and a second reactant by injecting the second reactant into the reaction chamber. According to the thin film manufacturing method according to the present invention, it is possible to grow a thin film on the substrate in a state in which the no or little impurities and physical defects are generated in the thin film and interface of the thin film.

This application relies for priority upon Korean Patent Application No. 98-43353, filed on Oct. 16, 1998, the contents of which are herein incorporated by reference in their entirety.

### BACKGROUND OF THE INVENTION

1. Field of the Invention

The present invention relates to a method for manufacturing a thin film used for a semiconductor device. More particularly, the present invention relates to a method for manufacturing a thin film by which it is possible to prevent the generation of impurities and physical defects in the thin film and an interface of the thin film.

2. Description of the Related Art

A thin film is typically used for a dielectric film of a semiconductor device, a transparent conductor of a liquid-crystal display, or a protective layer of an electroluminescent thin film display.

In particular, a thin film used for a dielectric film of a semiconductor device should have no impurities or physical defects in the dielectric film or in the interface of the dielectric film and the substrate, so as to obtain a high capacitance and a small leakage current. Also, the thin film should have an excellent step coverage and uniformity. Accordingly, a thin film used for the dielectric film of a semiconductor device must be formed in a surface kinetic regime in which reactants containing atoms comprising the thin film are fully moved, and thus the growth rate of the thin film is linearly increased according to the deposition time. To do so, the thin film is typically formed using a chemical vapor deposition (CVD) process. However, when manufacturing a thin film using a general CVD method, the atoms contained in a chemical ligand comprising the reactant remain during fabrication of thin film, which can thereby generate impurities in the thin film.

In order to solve the problem, deposition methods for activating the surface kinetic region by periodically supplying the reactant to the surface of a substrate have been proposed. For example, an atomic layer deposition (ALD) method, a cyclic chemical vapor deposition (CCVD) method, a digital chemical vapor deposition (DCVD) method, and an advanced chemical vapor deposition (ACVD) method have all been proposed.

However, the conventional deposition methods mentioned above generate impurities and physical defects in the thin film and the interface of the thin film during the fabrication of the thin film. Accordingly, they can deteriorate the characteristics of the thin film.

### SUMMARY OF THE INVENTION

It is an object of the present invention to provide a method for manufacturing a thin film by which it is possible to prevent the generation of impurities and physical defects in the thin film and an interface of the thin film.

To achieve the above object, a method for manufacturing a thin film is performed by loading a substrate into a reaction chamber and uniformly terminating dangling bonds on the surface of the substrate with a specific atom. Then, a first reactant is chemically adsorbed onto the terminated substrate by injecting the first reactant into the reaction chamber. After removing the first reactant physically adsorbed on the terminated substrate, a solid thin film is then formed through chemical exchange or reaction of the chemically adsorbed first reactant and a second reactant by injecting the second reactant into the reaction chamber.

As used in this specification, chemical adsorption is a reaction (or combination) between different species, while physical adsorption is a reaction (or combination) between the same species. In general, chemical adsorption has a bonding energy greater than that for physical adsorption.

Before loading the substrate into the reaction chamber, an impurity layer adsorbed into or formed on the surface of the substrate may be removed. A removal of an intermediate reactant generated during the formation of the solid thin film may be further included after forming a solid thin film. The surface of the substrate is preferably terminated by repeatedly injecting gas including the specific atom such as an oxygen or nitrogen atom at least twice.

A combination energy between an atom comprising the substrate and the specific atom is preferably larger than a combination energy between a ligand comprising the first reactant and the atom comprising the substrate. The solid thin film preferably a material selected from the group consisting of a single atomic thin film, a single atomic oxide, a composite oxide, a single atomic nitride, and a composite nitride.

In the method for manufacturing the thin film according to the present invention, it is possible to grow the thin film in a state where impurities and physical defects are not generated in the thin film and an interface between the thin film and the substrate.

### BRIEF DESCRIPTION OF THE DRAWINGS

The above object and advantages of the present invention will become more apparent by describing in detail a preferred embodiment thereof with reference to the attached drawings in which:

FIGS. 1 through 4 describe a method for manufacturing a thin film according to a preferred embodiment of the present invention;

FIG. 5 schematically shows an apparatus for manufacturing a thin film used for a method of manufacturing the thin film according to a preferred embodiment of the present invention;

FIG. 6 is a flowchart for describing a method of manufacturing the thin film according to a preferred embodiment of the present invention;

FIGS. 7 and 8 are graphs showing results of XPS analyses of aluminum oxide films manufactured by the thin film manufacturing methods according to a preferred embodiment of the present invention and a conventional technique; respectively;

FIG. 9 is a graph showing a leakage current characteristic of a capacitor using an aluminum oxide film manufactured in accordance with a preferred embodiment of the present invention as a dielectric film; and

FIG. 10 is a graph showing the capacitance of a capacitor using an aluminum oxide film manufactured in accordance with a preferred embodiment of the present invention as the dielectric film.

### DESCRIPTION OF THE PREFERRED EMBODIMENTS

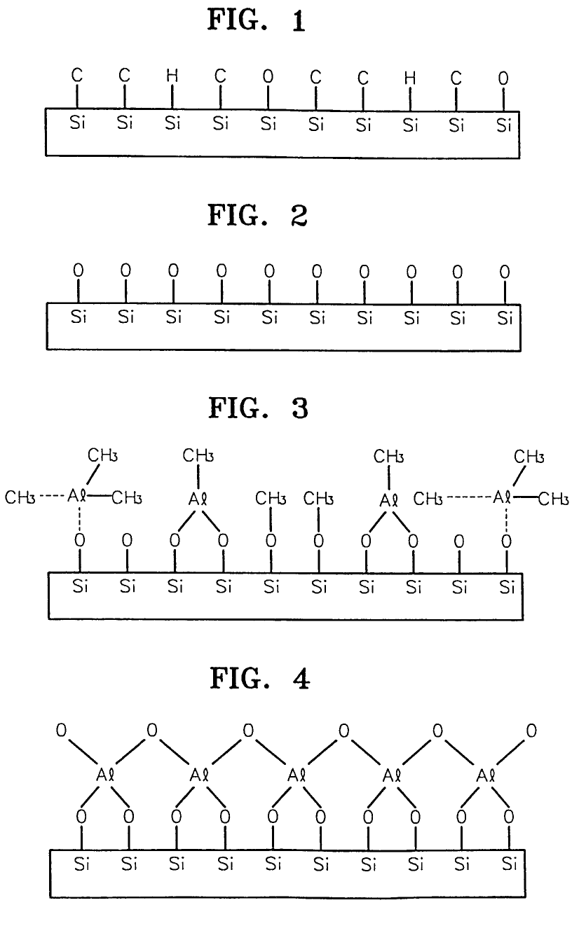

FIGS. 1 through 4 describe a method for manufacturing a thin film according to a preferred embodiment of the present invention.

Referring to FIG. 1, a semiconductor substrate, e.g., a silicon substrate is loaded into a reaction chamber. Silicon dangling bonds that are not combined with silicon atoms exist on the surface of the silicon substrate loaded in the reaction chamber after a preliminary heating process used for forming a thin film. As shown in FIG. 1, oxygen, carbon, or hydrogen atoms combine with the silicon dangling bonds. As a result, the surface of the silicon substrate can be contaminated by impurities. The carbon and hydrogen atoms preferably come from the ambient air or from the CH₃ used in a thin film fabrication process.

Impurities such as oxygen, carbon, or hydrogen atoms, existing on the interface of the silicon substrate, then become initial seeds for generating physical defects in the thin film and the interface of the thin film and the substrate when growing the thin film. Therefore, the defect density of the overall thin film can be lowered by reducing the amount of these initial impurities. Accordingly, prior to the formation of the thin film, the surface of the silicon substrate should be put into an optimal condition, in which the thin film may be homogeneously grown on the surface of the silicon substrate.

Referring to FIG. 2, the silicon dangling bonds are saturated by flushing them with oxygen atoms or nitrogen atoms to terminate the dangling bonds with the oxygen and nitrogen atoms, so that the thin film can be homogeneously grown on the surface of the silicon substrate. In other words, when an oxide and nitride film is deposited over the silicon substrate in a subsequent process, the bonds on the top surface of the substrate will be terminated by either oxygen or nitrogen, depending upon what gas is used for flushing the substrate. In FIG. 2, the substrate is shown to be terminated by oxygen atoms for illustrative purposes only.

By use of an oxygen or nitrogen saturation, the carbon or hydrogen atom that had combined with the silicon dangling bonds as shown in FIG. 1 are exchanged for oxygen or nitrogen atoms. As a result, substantially all of the silicon dangling bonds are combined with either an oxygen or nitrogen atom, and so the silicon dangling bonds are uniformly combined with oxygen or nitrogen atoms on the surface of the silicon substrate. The oxygen and nitrogen atoms displace the carbon and hydrogen atoms because a bonding force between an oxygen or nitrogen atom and a silicon atom is stronger than the bonding force between a carbon or hydrogen atom and a silicon atom, as shown in Table 1. In other words, a bonding energy between a silicon atom from the substrate and a specific atom is larger than the bonding energy between the carbon atom that comes from the ligand (CH₃) and the atom comprising the substrate.

TABLE 1
Bonding and Separation Energy between Atoms at 25° C.

| | Bonding and | | Bonding and |
|---|---|---|---|
| | Separation Energy | | Separation Energy |
| Bond | (kJ/mol) | Bond | (kJ/mol) |
| Al-C | 255 | Si-C | 435 |
| Al-O | 512 | Si-O | 798 |
| Al-H | 285 | Si-H | 298.49 |
| Al-N | 297 | Si-N | 439 |

When the surface of the silicon substrate is uniformly terminated by a single atom type, e.g., oxygen atoms, the surface of the silicon substrate becomes homogeneous. Accordingly, this prevents the generation of impurities and physical defects in the thin film and the interface of the thin film during a subsequent process, an allows for the formation of a homogeneous thin film. Oxygen and nitrogen atoms used for termination can be contributed to oxidation and nitrification as the second reactant, e.g., H₂O supplied in a subsequent step.

Referring to FIG. 3, a first reactant, for example, trimethylaluminum (TMA) Al(CH₃)₃ is supplied to the reaction chamber into which the terminated silicon substrate is loaded. Then, the reaction chamber is purged to remove any physically adsorbed first reactant, i.e., adsorbed reactant with a lower bonding energy. By doing so, only a chemically adsorbed first reactant is left on the silicon substrate, i.e., an adsorbed reactant with a higher bonding energy. Amounts of the remaining chemically-bonded first reactant CH₃ exist in various forms such as a Si—O—CH₃ radicals or a Si—O—Al—CH₃ radicals.

Referring to FIGS. 3 and 4, a second reactant, for example, H₂O is then injected into the reaction chamber including the silicon substrate onto which the first reactant is chemically adsorbed. The TMA reacts with the H₂O to form Al₂O₃ and CH₄. Then, the reaction chamber is purged to remove any physically adsorbed second reactant. By doing so, a solid thin film such as Al₂O₃ and an intermediate reactant such as a CH₄ radical are formed by the chemical exchange or the reaction between the chemically adsorbed first reactant and second reactant. Here, the Si—O—CH₃ radical is removed by injecting and purging the second reactant, and the CH₄ is removed by evaporation. Accordingly, a stable surface having a form of Si—O—Al—O is formed as shown in FIG. 4.

Accordingly, a dense interface is formed on the silicon substrate without impurities such as carbon and hydrogen atoms and the physical defects that would result from these impurities. Since the aluminum oxide film which continuously grows is deposited with a uniform underlayer, the density of the impurities and defects is lowered. In other words, since the state of an underlayer for every reactant is uniform in a surface reaction process performed by a ligand exchange due to the chemical absorption and the chemical reaction of reactants, the density of the thin film is high and the density of impurities and defects is lowered.

Here, a processes of forming a thin film using the method manufacturing the thin film according to a preferred embodiment of the present invention will be described in detail.

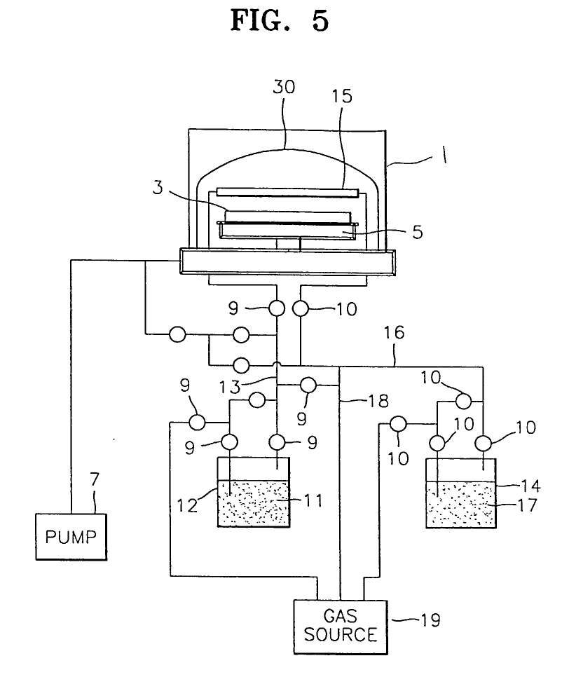

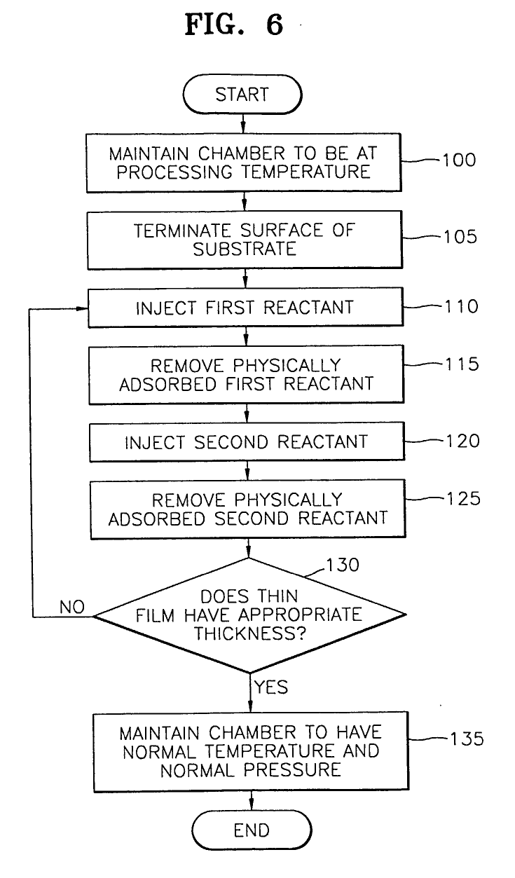

FIG. 5 schematically shows an apparatus for manufacturing a thin film used for the thin film manufacturing method according to a preferred embodiment of the present invention. FIG. 6 is a flowchart for describing the thin film manufacturing method according to a preferred embodiment of the present invention.

Initially, in this method, after loading the substrate 3, e.g., a silicon substrate, into a reaction chamber 30, the temperature of the substrate 3 is maintained at a temperature of preferably about 120 to 370° C., more preferably about 300° C., using a heater 5 (step 100). In order to maintain the temperature of the substrate 3 at about 300° C., the temperature of the heater 5 is preferably maintained at about 350° C. In addition, a further step of removing an impurity layer adsorbed or formed on the surface of the substrate 3 before loading the substrate 3 may be further included.

The surface of the silicon substrate 3 is terminated by nitrogen or oxygen atoms as shown in FIG. 2 by flushing nitrogen gas or oxygen gas into the reaction chamber 30 from a gas source 19 by selectively operating a valve 9 to the reaction chamber 30 and using a first gas line 13 or a second gas line 18 with a maintained processing temperature of about 120 to 370° C. (step 105). The surface of the silicon substrate can be more effectively terminated by repeatedly injecting the nitrogen gas or the oxygen gas at least two times.

If the surface of the silicon substrate is not terminated by nitrogen or oxygen atoms at a temperature of 120 to 370° C., both the silicon and the CH₃ radicals of the subsequently supplied first reactant are not decomposed. Accordingly, carbon impurities will exist on the silicon substrate. Hydrogen impurities remain on the silicon substrate as shown in FIG. 1.

A first reactant 11, e.g., Al(CH₃)₃ (TMA), is then continuously injected from a first bubbler 12 into the reaction chamber 30 for preferably about 1 millisecond to 10 seconds, more preferably, for about 0.3 seconds (step 110).

The first reactant 11 is preferably injected using a bubbling method. In other words, an inert gas, e.g., argon (Ar), of about 200 sccm (standard cubic centimeters) is preferably injected as a carrier gas from the gas source 19 into the first bubbler 12, which is preferably maintained at 20 to 22° C. As a result, the first liquid reactant 11 is changed into a gas state and the first gas reactant is injected through a first gas line 13 and a shower head 15 by selectively operating the valves 9 on the first gas line 13. At this time, the pressure of the reaction chamber 30 is preferably maintained to be about 1 to 5 Torr. Supplying the first reactant 11 in this manner, the first reactant 11, which is of about atomic size, is chemically adsorbed into the surface of the substrate 3. In addition to the chemically-adsorbed first reactant 11, a certain amount of the first reactant 11 will also be physically adsorbed on the substrate, over the chemically adsorbed first reactant 11.

The physically adsorbed first reactant is then removed, preferably by purging 400 sccm of nitrogen gas from the gas source 19 preferably for about 0.1 to 10 seconds, more preferably for about 0.9 seconds, by selectively operating the valve 9 leading to the reaction chamber 30 using the first gas line 13 or the second gas line 18 (step 115). This purging operation is preferably performed with the processing temperature of about 120 to 370° C. and a processing pressure of about 1 to 5 Torr.

A second reactant 17, e.g., deionized water contained in a second bubbler 14, is then injected into the reaction chamber 30 containing the substrate 3, through the gas line 13 and the shower head 15 for about 1 millisecond through 10 seconds, more preferably, for about 0.5 seconds, by selectively operating the valve 10 (step 120). This second injection operation is preferably carried out with a processing temperature of about 120 to 370° C. and a processing pressure of about 1 to 5 Torr.

Preferably, the second reactant 17 is also injected by a bubbling method similar to that used with the first reactant 11. Namely, the second liquid reactant 17 is changed into a gaseous form by injecting an inert gas, e.g., argon (Ar), into the second bubbler 14. The inert gas, which is used as a carrier gas for the gas source 19, is preferably at about 200 sccm and is preferably maintained at a temperature of about 20 to 22° C. The second reactant 17, in gaseous form, is then injected through a third gas line 16 and the shower head 15 into the reaction chamber 30. At this time, the pressure of the reaction chamber 30 is preferably maintained to be about 1 through 5 Torr.

By injecting the second reactant 17 into the reaction chamber 30, Al₂O₃ and CH₄ are formed by the chemical exchange or the reaction between the chemically adsorbed first reactant 11 and the second reactant 17. In other words, the combination of Al and CH₃ forms an Al₂O₃ radical and an CH₄ radical by reaction with H2O. The CH₄ radical is then removed during the subsequent purging process.

The physically adsorbed second reactant and any intermediate reactants are then removed by purging the reaction chamber with 400 sccm of nitrogen gas from the gas source 19 for about 0.1 to 10 seconds by selectively operating a valve 10 to the reaction chamber 30 (step 125). This is preferably done with a processing temperature of about 120 to 370° C. and a processing pressure of about 1 to 5 Torr.

It is then determined whether a thin film has an appropriate thickness (generally about 10 Å to 1,000 Å) (step 130). If the film does not have an appropriate thickness, the process of injecting the first and second reactants (steps 110 to 125) is repeated. When the thin film is determined in step 130 to have an appropriate thickness, the cycle is not repeated and the processing temperature and the processing pressure of the reaction chamber are returned to normal levels without repeating the above process (step 135). Accordingly, the processes of manufacturing the thin film is completed.

An aluminum oxide film Al₂O₃ can be formed when the first and second reactants are chosen to be Al(CH₃)₃ (TMA) and deionized water H₂O, respectively. A TiN film can be formed when the first and second reactants are chosen to be TiCI₄ and NH₃, respectively. An Mo film can be formed when the first and second reactants are chosen to be MoCl₅ and H₂, respectively.

Furthermore, using to the thin film manufacturing method according to a preferred embodiment of the present invention, it is possible to form a single atomic solid thin film, a single atomic oxide, a composite oxide, a nitrogen of a single atom, or a composite nitride. Al, Cu, Ti, Ta, Pt, Ru, Rh, Ir, W or Ag are examples of the single atomic solid thin film. TiO₂, Ta₂O₅, ZrO₂, HfO₂, Nb2O₅, CeO₂, Y₂O₃, SiO₂, In₂O₃, RuO₂, and IrO₂ are examples of the single atomic oxide. SrTiO₃, PbTiO₃, SrRuO₃, CaRuO₃, (Ba,Sr)TiO₃, Pb(Zr,Ti)O₃, (Pb,La)(Zr,Ti)O₃, (Sr,Ca)RuO₃, In₂O₃ doped with Sn, In₂O₃ doped with Fe, and In₂O₃ doped with Zr are examples of the composite oxide film. Also, SiN, NbN, ZrN, TaN, Ya₃N₅, AlN, GaN, WN, and BN are examples of the single atomic nitride. WBN, WSiN, TiSiN, TaSiN, AlSiN, and AlTiN are examples of the composite nitride.

As mentioned above, in the thin film manufacturing method according to the present invention, the injecting and purging of the first reactant and the injecting and purging of the second reactant are repeated with respect to the surface of the silicon substrate homogeneous by terminating the surface of the silicon substrate with hydrogen or oxygen atoms before injecting the first reactant. By doing so, it is possible to grow the thin film on the substrate in a state in which impurities and physical defects are not generated in the thin film and the interface of the thin film.

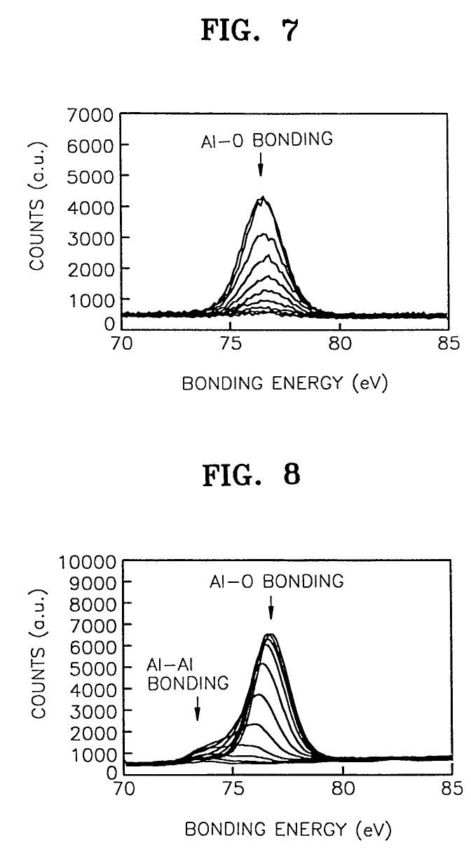

FIGS. 7 and 8 are graphs showing XPS analysis results of aluminum oxides manufactured by the thin film manufacturing methods according to a preferred embodiment of the present invention and a conventional technique, respectively.

To be specific, FIG. 7 shows an aluminum peak of an aluminum oxide film manufactured according to a preferred embodiment of the present invention; and FIG. 8 shows an aluminum peak of an aluminum oxide film manufactured according to a conventional technique. The X-axis denotes a bonding energy, and the Y-axis denotes electron counts in an arbitrary unit, which is a unitless number. As shown in FIG. 7, only Al—O bonding is shown in the aluminum oxide film according to the present invention from the surface to the interface. Al—Al bonding is shown in the interface in the conventional aluminum oxide film of FIG. 8, compared with FIG. 7. According to the present invention, it is possible to prevent the formation of the aluminum oxide film which lacks oxygen at the interface between the dielectric film and the substrate.

FIG. 9 is a graph showing a leakage current characteristic of a capacitor employing an aluminum oxide manufactured according to a preferred embodiment of the present invention as a dielectric film.

To be specific, an X-axis denotes a leakage current value, and a Y-axis denotes a distribution value of 20 points homogeneously arranged in an 8-inch wafer. A capacitor employing the aluminum oxide according to a preferred embodiment the present invention in which O₂ or H₂O are terminated shows the leakage current characteristic having a uniform distribution. A capacitor employing an aluminum oxide in which N₂ or NH₃ are terminated shows a partially weak leakage current characteristic.

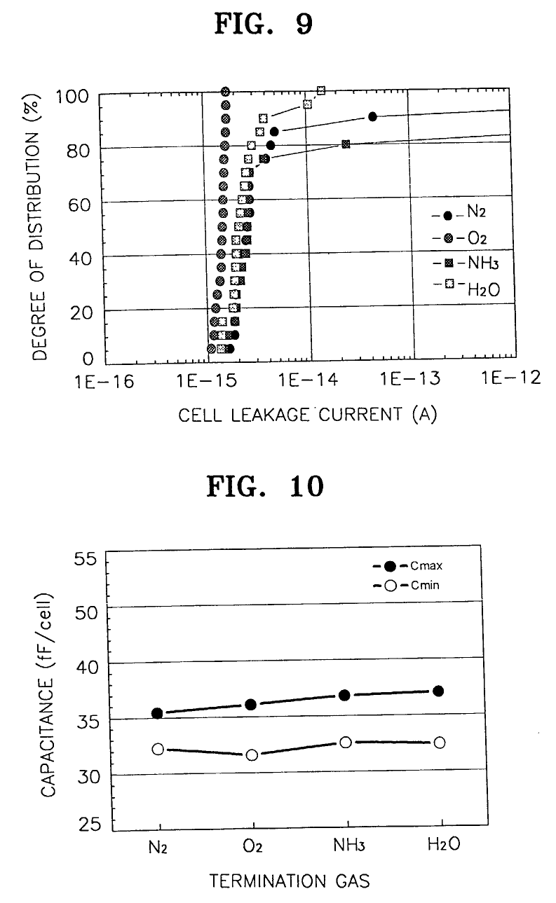

FIG. 10 is a graph showing the capacitance of a capacitor employing aluminum oxide manufactured according to a preferred embodiment of the present invention as a dielectric film.

To be specific, an X-axis, a Y-axis, Cₘₐₓ, and Cₘᵢₙ respectively denote a terminating gas, a capacitance value in a cell, a maximum capacitance, and a minimum capacitance. As can be seen in FIG. 10, whether the aluminum oxide film is employed as the dielectric film terminated by oxygen, nitride, ammonia, or a H₂O vapor the capacitance value is unaffected.

As mentioned above, according to the thin film manufacturing method of the present invention, the injecting and purging of the first reactant and the injecting and purging of the second reactant are repeatedly performed so that the surface of the silicon substrate is made homogeneous by terminating the surface of the silicon substrate before injecting the reactant. By doing so, it is possible to grow the thin film on the substrate with no impurities and physical defects generated in the thin film and interface of the thin film. Also, the thin film manufacturing method according to the present invention can be applied to all deposition methods for periodically providing and purging the reactant such as the ALD, the CCVD, the DCVD, and the ACVD.

The present invention is not restricted to the above embodiments, and it is clearly understood that many variations are possible within the scope and spirit of the present invention by anyone skilled in the art.

What is claimed is:

1. A method for manufacturing a thin film, comprising:
loading a substrate into a reaction chamber;
uniformly terminating dangling bonds on the surface of the substrate with a specific atom;
chemically adsorbing a first reactant onto the terminated substrate by injecting the first reactant into the reaction chamber;
removing any of the first reactant physically adsorbed into the terminated substrate; and
forming a solid thin film by chemical exchange or reaction of the chemically adsorbed first reactant and a second reactant by injecting the second reactant into the reaction chamber.

2. A method for manufacturing a thin film, as recited in claim 1, further comprising removing an impurity layer adsorbed into or formed on the surface of the substrate before loading the substrate into the reaction chamber.

3. A method for manufacturing a thin film, as recited in claim 1, further comprising a step of removing an intermediate reactant generated during the formation of the solid thin film after forming the solid film.

4. A method for manufacturing a thin film, as recited in claim 1, wherein the dangling bonds on the surface of the substrate are uniformly terminated by repeatedly injecting gas including the specific atom at least twice.

5. A method for manufacturing a thin film, as recited in claim 1, wherein the specific atom is one of a oxygen or a nitrogen atom.

6. A method for manufacturing a thin film, as recited in claim 1, wherein the substrate is a silicon substrate.

7. A method for manufacturing a thin film, as recited in claim 1, wherein the first reactant is Al(CH₃)₃ and second reactant is H2O.

8. A method for manufacturing a thin film, as recited in claim 1, wherein a combination energy between an atom comprising the substrate and the specific atom is larger than a combination energy between a ligand comprising the first reactant and the atom comprising the substrate.

9. A method for manufacturing a thin film, as recited in claim 1, wherein the solid thin film is one selected from the group consisting of a single atomic thin film, a single atomic oxide, a composite oxide, a single atomic nitride, and a composite nitride.

10. A method for manufacturing a thin film, as recited in claim 9, wherein the single atomic thin film is one selected from the group consisting of Mo, Al, Cu, Ti, Ta, Pt, Ru, Rh, Ir, W and Ag.

11. A method for manufacturing a thin film, as recited in claim 9, wherein the single atomic oxide is one selected from the group consisting of Al₂O₃, TiO₂, Ta₂O₅, ZrO₂, HfO₂, Nb₂O₅, CeO₂, Y₂O₃, SiO₂, In₂O₃, RuO₂, and IrO₂.

12. A method for manufacturing a thin film, as recited in claim 9, wherein the single atomic oxide is one selected from the group consisting of, PbTiO₃, SrRuO₃, CaRuO₃, (Ba,Sr)TiO₃, Pb(Zr,Ti)O₃, (Pb.La)(Zr,Ti)O₃, (Sr,Ca)RuO₃, In₂O₃ doped with Sn, In₂O₃ doped with Fe, and In₂O₃ doped with Zr.

13. A method for manufacturing a thin film, as recited in claim 9, wherein the single atomic nitride is one of SiN, NbN, ZrN, TiN, TaN, Ya₃N₅, AlN, GaN, WN, and BN.

14. A method for manufacturing a thin film, as recited in claim 9, wherein the composite nitride comprises a material selected from the group consisting of WBN, WSiN, TiSiN, TaSiN, AlSiN, and AlTiN.
